(19) United States
(12) Patent Application Publication
(10) Pub. No.: US 2016/0225830 A1
(43) Pub. Date: Aug. 4, 2016

(54) ORGANIC LIGHT EMITTING DIODE DISPLAY

(71) Applicant: SAMSUNG DISPLAY CO., LTD., Yongin-si (KR)

(72) Inventor: Nam Jin Jang, Busan (KR)

(21) Appl. No.: 14/861,763

(22) Filed: Sep. 22, 2015

(30) Foreign Application Priority Data
Feb. 2, 2015 (KR) 10-2015-0016354

(51) Int. Cl. H01L 27/32; G06F 1/16; G06F 3/041

(52) U.S. Cl. CPC H01L 27/323; G06F 3/0412; G06F 3/0416; G06F 1/16; G06F 2203/04102

(57) ABSTRACT

An organic light emitting diode display includes: display area where an image is not displayed, the non-display area including a first driver IC; a touch module above the display module and including a second driver IC; a first flexible printed circuit board (PCB) connected to the first driver IC; and a second flexible printed circuit board (PCB) connected to the second driver IC and including an extension configured to be in contact with the first driver IC.

### CROSS-REFERENCE TO RELATED APPLICATION

This application claims priority to and the benefit of Korean Patent Application No. 10-2015-0016354, filed in the Korean Intellectual Property Office on Feb. 2, 2015, the entire content of which is incorporated herein by reference.

### BACKGROUND

1. Field

Aspects of embodiments of the present invention relate generally to an organic light emitting diode display.

2. Description of the Related Art

A display device is a device that displays an image. In recent years, an organic light emitting diode display has attracted attention.

Organic light emitting diode displays have a self-emitting characteristic and may not require a separate light source, as opposed to liquid crystal display devices, which may include a separate light source. Therefore, the thickness and weight of organic light emitting diode displays may be reduced relative to other display devices such as liquid crystal display devices. Further, organic light emitting diode displays exhibit high quality characteristics such as relatively low power consumption, high luminance, and high reaction speed.

In a configuration of the organic light emitting diode display, an on-cell touch screen AmOLED (OCTA) may include an organic emission layer, a display module that is divided into a display area and a non-display area, and a touch module that is located above the display module. The on-cell touch screen configuration may include a small thickness and high optical transmittance and may include a relatively narrow bezel, therefore, the on-cell touch screen configuration is suitable for a current trend toward reducing or omitting a bezel (e.g., in a bezel-less configuration).

However, when the on-cell touch screen AmOLED is applied to a display device of a wearable apparatus, a structure of the display module and the touch module may be limited due to the unique shape of the wearable apparatus such as a smart watch or a head mount display and thus the structure of a driver IC and a flexible printed circuit board (FPCB) that are connected to the display module and the touch module is also restrictively designed. Therefore, it may be difficult to control the electrostatic discharge (ESD) generated in the touch panel and the display module and the heat generated in the display module driver IC.

The above information disclosed in this Background section is only for enhancement of understanding of the background of the described technology and therefore it may contain information that does not constitute prior art.

### SUMMARY

Aspects of embodiments of the present invention relate generally to an organic light emitting diode display, and more particularly, to an organic light emitting diode display in which heating and electrostatic discharge (ESD) characteristics of a driver IC are improved.

According to aspects of example embodiments of the present invention, an organic light emitting diode display changes a structure of a flexible PCB that connects driver ICs mounted in a display module and a touch module to each other to reduce or minimize the heat generated in the driver IC and the ESD generated in the touch panel and the display module.

According to one or more example embodiments of the present invention, an organic light emitting diode display includes: a display module including a display area where an image is displayed and a non-display area where an image is not displayed, the non-display area including a first driver IC; a touch module above the display module and including a second driver IC; a first flexible printed circuit board (PCB) connected to the first driver IC; and a second flexible printed circuit board (PCB) connected to the second driver IC and including an extension configured to be in contact with the first driver IC.

A shape of the display area may be circular.

The non-display area may include a first non-display unit adjacent the display area and including a ring shape enclosing the display area and a second non-display unit protruding outside the first non-display unit in a first direction.

The first driver IC may be in the second non-display unit.

The touch module may include a circular shaped first part, and a second part protruding outside the first part in a second direction.

The second driver IC may be in the second part.

The first direction and the second direction may be a same direction.

The extension may cover an upper surface of the first driver IC.

According to one or more example embodiments of the present invention, in an organic light emitting diode display, the extension extending from the first flexible printed circuit board (PCB) may be in contact with the first driver IC, which may minimize the ESD and simultaneously, the extension may be formed to cover all or a part of the outside of the first driver IC, which may improve the heating characteristic of the first driver IC.

According to one or more example embodiments of the present invention, in an organic light emitting diode display, protruding directions of the second non-display unit and the second part may be designed in various ways, to be applied to wearable display devices such as a smart watch or a head mount display device.

### BRIEF DESCRIPTION OF THE DRAWINGS

FIG. 1 is a plan view of an organic light emitting diode display, according to example embodiments of the present invention.

FIG. 2 is a perspective view illustrating heat transfer path of the organic light emitting diode display, according to example embodiments of the present invention.

FIGS. 3A and 3B are images of comparing a path 1 of FIG. 2 with a heating profile of a general organic light emitting diode display (FIG. 3A) and an organic light emitting diode display (FIG. 3B), according to example embodiments of the present invention.

FIG. 4 is another plan view of an organic light emitting diode display, according to example embodiments of the present invention.

### DETAILED DESCRIPTION

Hereinafter, example embodiments of the present invention will be described in some detail with reference to the accompanying drawings so as for those skilled in the art to carry out the present invention. As those skilled in the art would realize, the described embodiments may be modified in various different ways, all without departing from the spirit or scope of the described technology. The drawings and description are to be regarded as illustrative in nature and not restrictive. Like reference numerals designate like elements throughout the specification.

In addition, unless explicitly described to the contrary, the word “comprise” and variations such as “comprises” or “comprising,” will be understood to imply the inclusion of stated elements but not the exclusion of any other elements. Further, in the specification, when a part is connected to a configuration, the part may be not only physically directly connected, but also electrically connected to the configuration.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

In the described technology, the organic light emitting diode display is defined to include not only a flat panel display such as a mobile communication terminal or a television, but also various wearable display devices having a unique shape such as a smart watch or a head mount display.

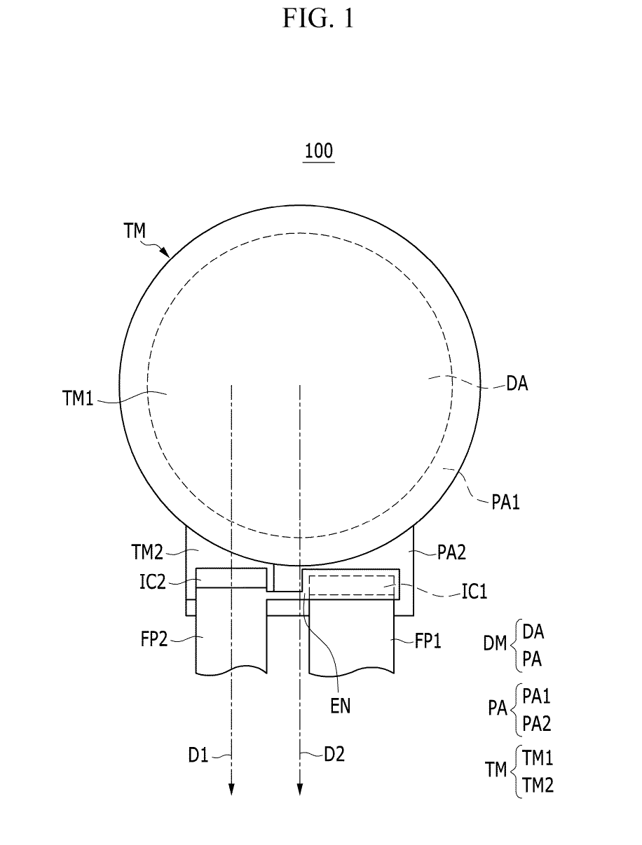

FIG. 1 is a plan view of an organic light emitting diode display according to an example embodiment.

As illustrated in FIG. 1, an organic light emitting diode display 100 according to an example embodiment includes a display module DM, a touch module TM, a first flexible printed circuit board (PCB) FP1, and a second flexible printed circuit board (PCB) FP2.

A display module DM includes regions which are defined as a display area DA where an image is displayed and a non-display area PA where an image is not displayed and may include a flexible substrate (not illustrated) such as plastic to have flexibility.

The display area DA is defined as a region where an organic emission layer (not illustrated) is provided to control an emission degree of the organic emission layer by an electric signal so that an image is displayed. According to example embodiments of the present invention, as illustrated in FIG. 1, the display area DA having a generally circular structure or circular shape is disclosed and a circular display area DA is formed so that the organic light emitting diode device 100 according to example embodiments may be applied to various wearable display devices such as a circular smart watch. However, the scope of example embodiments of the present invention are not limited thereto, but the display area having polygon such as a triangle or a quadrangle or various shapes such as an oval, a star, or a tumbler shape may be formed so as to correspond the display area of various wearable display devices.

The non-display area PA is a remaining region excluding the display area DA and is defined as a region including a plurality of wiring lines extending from the display area DA. The non-display area PA may include a first driver IC 101 which is connected to the plurality of wiring lines to control a driving signal of the display area.

An organic emission layer (not illustrated) of the above-described display area DA, an arrangement structure of electrodes, or a connection structure between wiring lines of the non-display area PA, an arrangement structure of the plurality of wiring lines are already known, and detailed description thoseof will be omitted.

In the meantime, the non-display area PA may include a first non-display unit (or first non-display area) PA1 and a second non-display unit (or second non-display area) PA2.

The first non-display unit PA1 is adjacent to the display area DA and according to some example embodiments of the present invention, the first non-display unit PA1 may be formed to have, for example, a ring shape, and may enclose or surround the entire external diameter or periphery of the circular display area DA, as illustrated in FIG. 1. However, the shape of the first non-display unit PA1 is not necessarily limited thereto, but may be formed to have various shapes in accordance with the shape of the display area DA, for example, a triangular or a quadrangular ring shape.

The second non-display unit PA2 may protrude from an outside (e.g., an outside edge) of the first non-display unit PA1 and extend in a first direction D1, as illustrated in FIG. 1. The first driver IC IC1 is mounted on an upper surface of the second non-display unit PA2 and the first driver IC IC1 is connected to a wiring line which extends from the first non-display unit PA1.

In the example embodiments, the first direction D1 may be located on a plane parallel to a plane on which the region DA is located and, as illustrated in FIG. 1, may be the external diameter direction of the first non-display unit PA1, but the scope of the example embodiments is not limited thereto. The first direction D1 may be various directions in accordance with a shape of the organic light emitting diode display 100. That is, the first direction D1 may be a circumferential direction of the first non-display unit PA1 or a direction which is not parallel to both the external diameter direction of the first non-display unit PA1 and a circumferential direction or a direction which is not parallel to the plane on which the region DA is located.

The touch module TM is located above the display module DM and includes a second driver IC and applies an input signal to an image displayed in the display module DM. The touch module TM includes a first part TM1 and a second part TM2.

The first part TM1 includes a plurality of touch electrodes and is directly applied with a touch signal and may be formed to be larger than the display area DA so that a touch input based signal is applied to the display area DA. According to example embodiments of the present invention, the first part TM1 is formed to have a circular shape corresponding to the circular display area DA, as illustrated in FIG. 1, but the scope of the example embodiments is not limited thereto and the first part TM1 may be formed to have various shapes in accordance with the shape of the display area DA.

The second part TM2 is a region including a wiring unit extending from the first part TM1 and as illustrated in FIG. 1, may protrude from the outside of the first part TM1 to the second direction D2. Further, a second driver IC IC2 is mounted in the second part TM2 and the second driver IC IC2 is connected to the wiring unit extending from the first part TM1. The second part TM2 may be arranged or positioned so as not to block the upper portion of the first driver IC IC1 with respect to a plane seen from the upper portion of the touch module TM.

In the example embodiments, the first direction D1 may be the same as the second direction D2. That is, the second non-display unit PA2 and the second part TM2 may be arranged or positioned to extend parallel to each other. As illustrated in FIG. 1, the second direction D2 may be a direction which is not parallel to both the external direction of the first part TM1 and the circumferential direction, as illustrated in FIG. 1. However, the scope of the example embodiments is not limited thereto but similarly to the above-described first direction D1, the second direction may be various directions in accordance with the shape of the organic light emitting diode display 100 and may be a different direction from the first direction D1.

As described above, according to example embodiments of the present invention, the second non-display unit PA2 in which the first driver IC IC1 is mounted and the second part TM2 in which the second driver IC ICI2 is mounted protrude or extend outside the first non-display unit PA1 and the first part TM1, respectively, so that a fine view of a display unit of the wearable display device such as a smart watch or a head mount display is improved and arrangement of the second non-display unit PA2 and the second part TM2 varies depending on the first direction D1 and the second direction D2 to be applied to the wearable display device.

Further, in the example embodiments, when the second non-display unit PA2 is arranged to be parallel to the second part TM2, a part such as a frame or a band that is connected to the display unit of the wearable display device may be easily designed.

The first flexible printed circuit board (PCB) FP1 is connected to the first driver IC IC1 to supply an electric signal required to control the driving of the display module DM and the second flexible printed circuit board (PCB) FP2 is connected to the second driver IC IC2 to transmit input and output signals of the touch module TM to the display module DM. In the meantime, in the present example embodiment, the second flexible printed circuit board (PCB) FP2 includes an extension EN.

The extension EN may extend toward the first driver IC IC1 to be in contact with the first driver IC IC1 from the side of the second flexible printed circuit board (PCB) FP2. According to the first example embodiment of the present invention, as illustrated in FIG. 1, even though the extension EN is formed to cover only the entire upper surface of the first driver IC IC1, the extension EN may extend to cover all or a part of the outside of the first driver IC IC1. In the extension EN, a printing pattern may be removed so as to prevent or reduce instances of a short circuit with the first flexible printed circuit board (PCB) FP1. As described above, in the example embodiment, the extension EN is in contact with the second flexible printed circuit board (PCB) FP2 to remove a potential difference with the first driver IC IC1 so that electrostatic discharge ESD due to a potential difference between the display module DM and the touch module TM may be minimized.

Further, according to example embodiments of the present invention, the extension EN is formed to cover all or a part of the outside of the first driver IC IC1 so that heat discharged from the first driver IC IC1 may be primarily blocked by the extension EN which covers the first driver IC IC1 so that heating characteristic of the first driver IC IC1 may be improved.

Hereinafter, an experimental example of an effect of improving the heating characteristic of the organic light emitting diode display 100 according to example embodiments of the present invention will be described.

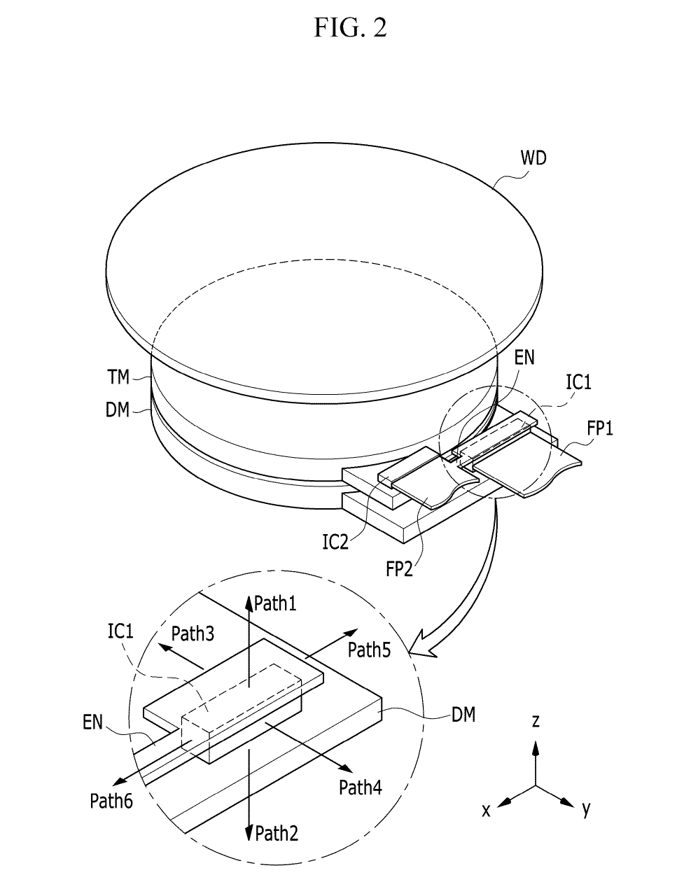

FIG. 2 is a perspective view illustrating a heat transfer path of the organic light emitting diode display 100 according to example embodiments of the present invention.

When the organic light emitting diode display 100, which includes a first driver IC IC1 having a size of a length of a y-axis direction of 30.9 mm, a length of an x-axis direction of 1.53 mm, a length of a z-axis direction of 0.25 mm, is driven, as illustrated in FIG. 2, the heat generated from the first driver IC IC1 is transmitted in an upper direction (the z-axis direction, path 1) of the first driver IC IC1, a lower direction (−z axis direction, path 2), an inner direction (−y-axis direction, path 3) of the display module DM, an outer direction (y-axis direction, path 4) of the display module DM, a back side direction (−x-axis direction, path 5) of FIG. 2, and a front direction (x-axis direction, path 6) of FIG. 2.

When it is assumed that a heat transfer coefficient of an internal air of the organic light emitting diode display 100 which is consistently 0.023 W/mK and heat transfer coefficients of the display module DM and the window substrate WD are same as 0.92 W/mK, and a physical property indicating that thermal conductivity is decreased in the order of solid, liquid, and air is considered, the heat transfer ranking for the heat transfer directions is represented in Table 1.

TABLE 1

| | | Heat transfer | Heat | Heat |
|---|---|---|---|---|
| | | coefficient | transfer | transfer |
| | Heat transfer medium | (W/mK) | area mm² | ranking |
| Path 1 | Air/window substrate | 0.023/0.92 | 30.9 * 1.53 | 2 |
| Path 2 | Display module | 0.92 | 30.9 * 1.53 | 1 |
| Path 3 | Air/display panel | 0.023/0.92 | 30.9 * 0.25 | 3 |
| Path 4 | Air | 0.023 | 30.9 * 0.25 | 4 |
| Path 5 | Air | 0.023 | 1.53 * 0.25 | 5 |
| Path 6 | Air | 0.023 | 1.53 * 0.25 | 6 |

Referring to Table 1, in the case of the first driver IC IC1, in the path 2 direction, the heat transfer raking is the highest and the heat transfer degree in the path 5 and the path 6 is significantly lower than the heat transfer degree in the paths 1 to 4.

In the case of the path 2, which is the highest of the heat transfer rankings, it may be determined that the heat is inevitably generated by the contact between the first driver IC IC1 and the display module DM and in the example embodiment, the first driver IC IC1 is mounted in the second non-display unit PA2, which is spaced apart from the display unit DA, so that the heat transmitted to the display module DM by the path 1 does not substantially affect the display module DM.

However, when the air is included as a heat transfer medium like the path 1, path 3, and path 4, the heat generated from the path 1, the path 3, and the path 4 may affect the display unit DA along the side of the display module DM. Therefore, as illustrated in FIG. 2, the extension EN covers and protects the outside of the first driver IC 101 so that the heat generated from the first driver IC IC1 is primarily blocked through the extension EN, thereby improving the heating characteristic of the first driver IC IC1.

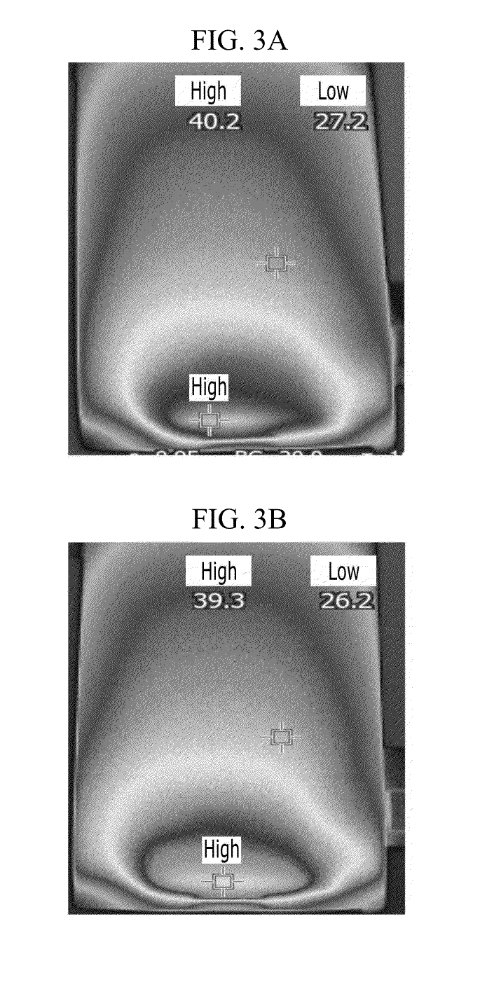

FIGS. 3A and 3B are images of comparing a path 1 of FIG. 1 with a heating profile of a general organic light emitting diode display (FIG. 3A) and an organic light emitting diode display (FIG. 3B) according to example embodiments of the present invention.

Referring to FIGS. 3A and 3B, in the case of organic light emitting diode display which does not have a separate configuration which covers the first driver IC, a highest temperature at the upper surface of the first driver IC is 40.2° C. and a lowest temperature in the internal direction of the display panel is 27.2° C. In contrast, in the case of the organic light emitting diode display 100 according to the example embodiments of the present invention, a highest temperature at the upper surface of the first driver IC is 39.3° C. and a lowest temperature in the internal direction of the display panel is 26.2° C. That is, in the organic light emitting diode display 100 according to example embodiments of the present invention, in the path 1 of FIG. 2, heating improvement of approximately 1° C. may be obtained.

As described above, according to the organic light emitting diode display 100 according to example embodiments of the present invention, the extension EN covers all or a part of the outside of the first driver IC IC1, so that the heating characteristic by the driving of the first driver IC IC1 is improved. Further, the extension EN is in contact with the first driver IC IC1 to remove the potential difference between the first driver 101 and the extension, so that the ESD generated between the touch module TM and the display module DM may be minimized.

Further, according to the organic light emitting diode display 100 according to example embodiments of the present invention, protruding directions of the second non-display unit PA2 and the second part TM2 may be designed in various ways so that the organic light emitting diode display may be easily applied to the wearable display device such as a smart watch or a head mount display device.

Hereinafter, an organic light emitting diode display 200 according to a second example embodiment will be described. When the second example embodiment is described, the same configuration as the configuration of the organic light emitting diode display 100 according to the first example embodiment is denoted by the same reference numerals and some repetitive detailed description will be omitted.

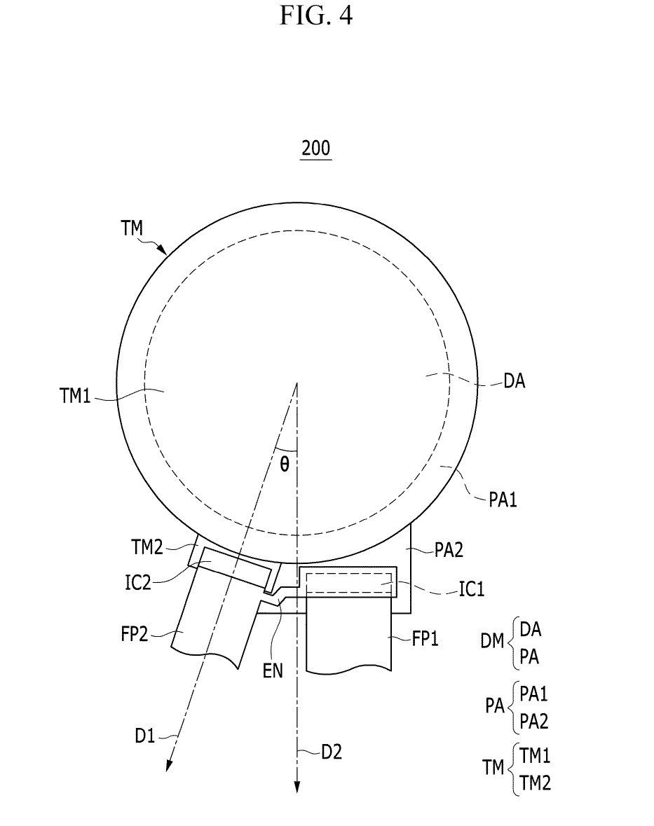

FIG. 4 is a plan view of an organic light emitting diode display 200 according to a second example embodiment.

Referring to FIG. 4, the organic light emitting diode display 200 according to the second example embodiment have the same configuration as the organic light emitting diode display 100 according to the first example embodiment, excepting that the first direction D1 is different from the second direction D2. That is, in the organic light emitting diode display 200 according to the second example embodiment, protruding directions of the second non-display unit PA2 and the second part TM2 are not parallel to each other and as compared with FIG. 1, the touch module TM rotates at a predetermined angle θ in a counterclockwise direction to be positioned above the display module DM.

In the case of the organic light emitting diode display 200 according to the second example embodiment, as illustrated in FIG. 4, at least a part of the extension EN may be bent so as to enclose the outside of the first driver IC IC1. As described above, a bending degree of the extension EN may be adjusted in various ways in accordance with various rotation angles 8 formed by the touch module TM and the display module DM so that even when the first direction D1 and the second direction D2 are different from each other, the heating characteristic of the first driver IC IC1 may be improved and the ESD generated between the display module DM and the touch module TM may be minimized.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims, and their equivalents.

Description of some of the symbols

100, 200: Organic light emitting diode display

| | |
|---|---|
| DM: Display module | DA: Display area |
| PA: Non-display area | PA1: First non-display unit |
| PA2: Second non-display unit I | C1: First driver IC |
| D1: First direction | D2: Second direction |
| TM: Touch module | TM1: First part |
| TM2: Second part | IC2: Second driver IC |
| FP1: First flexible printed circuit board | |
| FP2: Second flexible printed circuit board | |
| EN: Extension | |
| WD: Window substrate | |

What is claimed is:

1. An organic light emitting diode display, comprising:
a display module comprising a display area where an image is displayed and a non-display area where an image is not displayed, the non-display area comprising a first driver IC;
a touch module above the display module and comprising a second driver IC;
a first flexible printed circuit board (PCB) connected to the first driver IC; and
a second flexible printed circuit board (PCB) connected to the second driver IC and comprising an extension configured to be in contact with the first driver IC.

2. The organic light emitting diode display of claim 1, wherein:
a shape of the display area is circular.

3. The organic light emitting diode display of claim 2, wherein:
the non-display area comprises a first non-display unit adjacent the display area and comprising a ring shape enclosing the display area and a second non-display unit protruding outside the first non-display unit in a first direction.

4. The organic light emitting diode display of claim 3, wherein:
the first driver IC is in the second non-display unit.

5. The organic light emitting diode display of claim 3, wherein:
the touch module comprises a circular shaped first part, and
a second part protruding outside the first part in a second direction.

6. The organic light emitting diode display of claim 5, wherein:
the second driver IC is in the second part.

7. The organic light emitting diode display of claim 5, wherein:
the first direction and the second direction are a same direction.

8. The organic light emitting diode display of claim 1, wherein:
the extension covers an upper surface of the first driver IC.
